(19) United States
(12) Patent Application Publication
(10) Pub. No.: US 2016/0343602 A1
(43) Pub. Date: Nov. 24, 2016

(54) WORKPIECE CLAMP

(71) Applicant: Episil Technologies Inc., Hsinchu City (TW)

(72) Inventor: Chi-Hung Tien, Hsinchu City (TW)

(21) Appl. No.: 14/809,272

(22) Filed: Jul. 26, 2015

(30) Foreign Application Priority Data
May 21, 2015 (TW) 104116284

(51) Int. Cl. H01L 21/687

(52) U.S. Cl. CPC H01L 21/68721

(57) ABSTRACT

A workpiece clamp including an inner ring is provided. The inner edge of the inner ring can be divided into a circular arc portion and two first line portions. The first line portions are connected to each other and located at the notch of the circular arc portion. The circular arc portion has a circle centre. The first line portions are connected at a connecting point. The included angle between the connecting line from the circle centre to the connecting point and each first line portion is greater than about 90 degrees and less than about 93 degrees.

### CROSS REFERENCE TO RELATED APPLICATION

This application claims the priority benefit of Taiwan application serial no. 104116284, filed on May 21, 2015. The entirety of the above-mentioned patent application is hereby incorporated by reference herein and made a part of specification.

### BACKGROUND OF THE INVENTION

1. Field of Invention

The present invention is related to a semiconductor part, and more particularly to a workpiece clamp.

2. Description of Related Art

Thin film deposition has been one of the most widely applied techniques in the semiconductor industry. Thin film deposition can be divided into a physical vapour deposition (PVD) and a chemical vapour deposition (CVD). The former is carried out through a physical phenomenon, while the latter is carried out through a chemical reaction. No matter what kind of vapour deposition is carried out, a deposition machine is required for the related processes.

The wafer is usually fixed by the wafer clamp on a deposition machine and then subjected to a surface deposition process. However, when the wafer clamp of the deposition machine shifts, the abnormal peripheral indent occurs. Therefore, the wafer deposition performance is deteriorated and the yield is reduced.

### SUMMARY OF THE INVENTION

Accordingly, the present invention provides an improved workpiece clamp, in which the flat portions of the inner ring are controlled to have a specific angle therebetween, so as to effectively resolve the peripheral indent issues in the art.

The present invention provides a workpiece clamp including an inner ring. The inner edge of the inner ring is divided into a circular arc portion and two first line portions. The first line portions are connected to each other and located at the notch of the circular arc portion. The circular arc portion has a circle centre. The first line portions are connected at a connecting point. An included angle between a connecting line from the circle centre to the connecting point and each first line portion is greater than about 90 degrees and less than about 93 degrees.

According to an embodiment of the present invention, the included angle between the connecting line from the circle centre to the connecting point and each first line portion is greater than about 90 degrees and less than or equal to about 92 degrees.

According to an embodiment of the present invention, the included angle between the connecting line from the circle centre to the connecting point and each first line portion is from about 91 degrees to 92 degrees.

According to an embodiment of the present invention, a bottom surface of the inner ring comprises an annular plane adjacent to the inner edge and an annular ramp extending outwardly from the annular plane.

According to an embodiment of the present invention, an included angle between the annular plane and the annular ramp is from about 115 degrees to 125 degrees.

According to an embodiment of the present invention, an outer edge of the inner ring has two separate second line portions.

According to an embodiment of the present invention, the first line portions are opposite to one of the second line portions.

According to an embodiment of the present invention, the first line portions have substantially the same length.

According to an embodiment of the present invention, the first line portions have different lengths.

According to an embodiment of the present invention, the workpiece clamp further includes an outer ring configured to engage with the inner ring.

In view of the above, in the present invention, the flat portions of the inner ring of the workpiece clamp are designed to have a specific angle therebetween. With such design, the inner ring shift is significantly reduced, the abnormal products are less produced, the maintenance cost is lowered, and the machine stability is enhanced.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of an inner ring of a workpiece clamp according to an embodiment of the present invention.

FIG. 1B is a cross-sectional view of the inner ring taken along the line I-I of FIG. 1A with an enlarged local view illustrated below.

FIG. 2A is a cross-sectional view of a workpiece clamp in a machine idle position according to an embodiment of the present invention.

FIG. 2B is a cross-sectional view of a workpiece clamp in a machine active position according to an embodiment of the present invention.

FIG. 3A is a top view of a workpiece and a workpiece clamp under a normal condition according to an embodiment of the present invention.

FIG. 3B is a top view of a workpiece and a workpiece clamp under a shift condition according to an embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

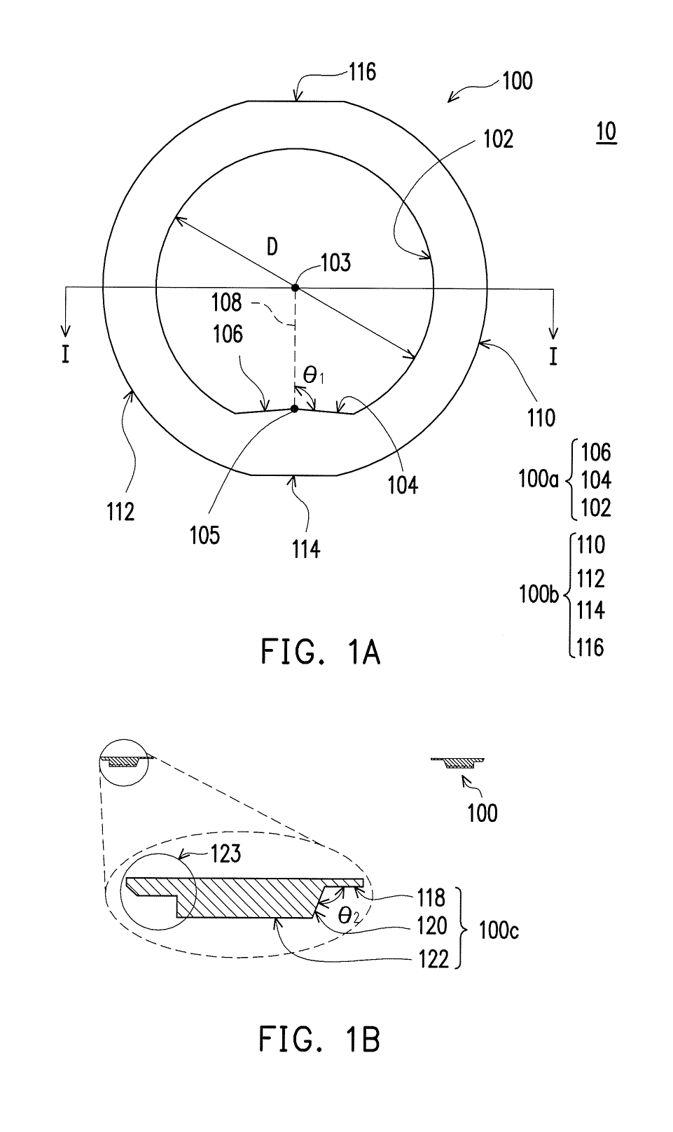

FIG. 1A is a top view of an inner ring of a workpiece clamp according to an embodiment of the present invention. FIG. 1B is a cross-sectional view of the inner ring taken along the line I-I of FIG. 1A with an enlarged local view illustrated below.

Referring to FIG. 1A and FIG. 1B, a workpiece clamp 10 includes an inner ring 100. The inner edge 100a of the inner ring 100 is divided into a circular arc portion 102 and two first line portions 104 and 106.

The first line portions 104 and 106 are connected to each other and located at the notch or opening of the circular arc portion 102. The circular arc portion 102 has a circle centre 103. The first line portions 104 and 106 are connected at a connecting point 105. The included angle θ₁ between a connecting line 108 from the circle centre 103 to the connecting point 105 and each of the first line portions 104 and 106 is greater than about 90 degrees and less than about 93 degrees. In an embodiment, the included angle θ₁ is greater than about 90 degrees and less than or equal to about 92 degrees. In another embodiment, the included angle θ₁ can be from about 91 degrees to 92 degrees. Specifically, the included angle θ₁ can be 90.1, 90.2, 90.3, 90.4, 90.5, 90.6, 90.7, 90.8, 90.9, 91.0, 91.1, 91.2, 91.3, 91.4, 91.5, 91.6, 91.7, 91.8, 91.9, 92.0, 92.1, 92.2, 92.3, 92.4, 92.5, 92.6, 92.7, 92.8 or 92.9 degrees, or any value between two of the said numbers.

In the present invention, the first line portions 104 and 106 of the present invention constitute the “flat” or “flat portions” of the inner ring 100. Although the first line portions 104 and 106 form a slightly V-type concave shape rather than a linear shape, they are described as “flat” or “flat portions” through the specification.

In an embodiment, when the first line portions 104 and 106 have substantially the same length, the included angle θ₁ between the connecting line 108 from the circle centre 103 to the connecting point 105 and each of the first line portions 104 and 106 is the same. In other words, the first line portions 104 and 106 are disposed symmetrically with respect to the connecting line 108. In this case, the included angle between the first line portions 104 and 106 can be 2×θ₁. However, the present invention is not limited thereto.

In another embodiment, when the first line portions 104 and 106 have different lengths, the included angle θ₁ between the connecting line 108 from the circle centre 103 to the connecting point 105 and each of the first line portions 104 and 106 is different. In other words, the first line portions 104 and 106 are disposed unsymmetrically with respect to the connecting line 108.

In an embodiment, when the workpiece clamp 10 of the present invention is applied to a six-inch workpiece such as a six-inch wafer, each of the first line portions 104 and 106 has a length of about 33 μm to 35 μm (e.g., about 34 μm), and the circular arc portion 102 has a diameter D of about 143 μm to 146 μm (e.g., 144 μm). In another embodiment, when the workpiece clamp 10 of the present invention is applied to other size workpiece, the lengths of the first line portions 104 and 106 and the diameter of the circular arc portion 102 can be adjusted as needed.

Besides, as shown in FIG. 1B, the bottom surface 100c of the inner ring 100 includes an annular plane 118, an annular ramp 120 and another annular plane 122. The annular plane 118 is adjacent to the inner edge 100a. The annular ramp 120 extends outwardly from the annular plane 118 and is adjacent to another annular plane 122. Besides, included angle θ₂ between the annular plane 118 and the annular ramp 120 is about 115 degrees to 125 degrees, such as about 120 degrees. The annular ramp 120 is configured for the alignment of the workpiece. In an embodiment, when the workpiece is raised to a machine active position and is not directly positioned to the interface (can be regarded as an alignment point) between the annular plane 118 and the annular ramp 120, the workpiece can slide to the alignment point via the annular ramp 120, and thus, the edge of the workpiece is in contact with the annular plane 118.

In addition, as shown in FIG. 1A, the outer edge 100b of the inner ring 100 can be divided into separate circular arc portions 110 and 112 and separate second line portions 114 and 116. The circular arc portions 110a and 112 and the second line portions 114 and 116 are arranged alternately. Specifically, the outer edge 100b has a circular arc portion 110, a second line portions 114, a circular arc portion 112 and a second line portions 116 arranged in sequence.

In an embodiment, the circle centre of the circular arc portions 110 and 112 of the outer edge 100b is the circle centre 103 of the circular arc portion 102 of the inner edge 100a, as shown in FIG. 1A, but the present invention is not limited thereto. In another embodiment, the circle centre of the circular arc portions 110 and 112 of the outer edge 100b is not overlapped with the circle centre 103 of the circular arc portion 102 of the inner edge 100a. Besides, the first line portions 104 and 106 of the inner edge 100a of the inner ring 100 are disposed corresponding to or opposite to the second line portion 114 of the outer edge 100b of the same.

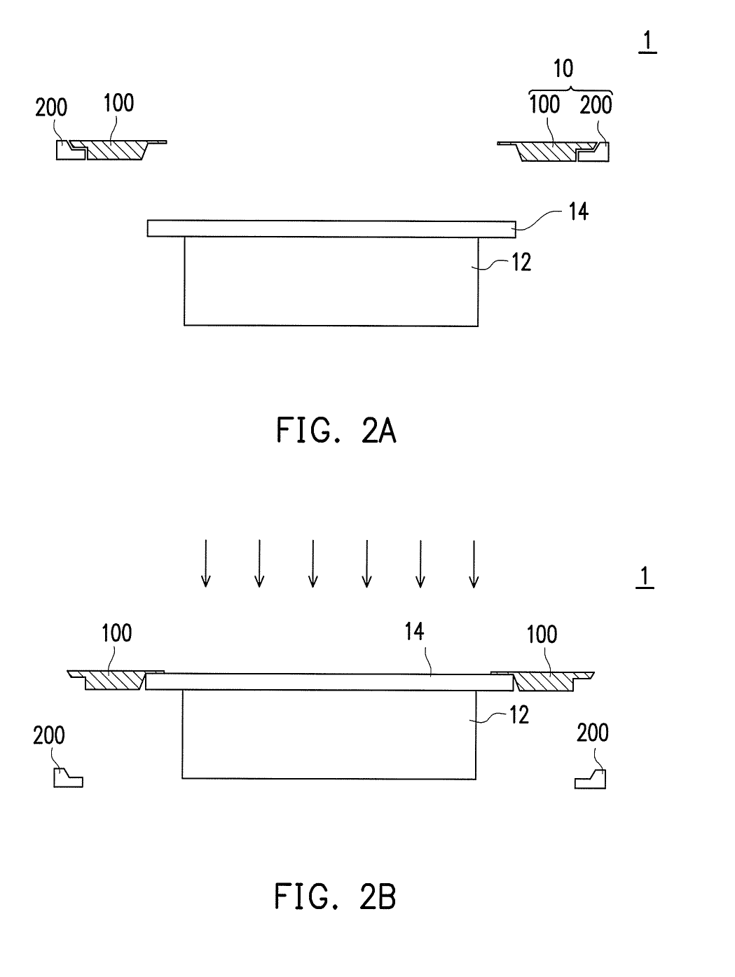

FIG. 2A is a cross-sectional view of a workpiece clamp in a machine idle position according to an embodiment of the present invention. FIG. 2B is a cross-sectional view of a workpiece clamp in a machine active position according to an embodiment of the present invention.

A vapour deposition machine 1 can includes a workpiece clamp 10 and a workpiece stage 12. The workpiece clamp 10 is located above the workpiece stage 12. The vapour deposition machine 1 can be a physical vapour deposition (PVD) machine or a chemical vapour deposition (CVD) machine. In an embodiment, the vapour deposition machine 1 can be a tungsten (wolfram) chemical vapour deposition (WCVD) machine. The workpiece clamp 10 can include an inner ring 100 and an outer ring 200. The inner ring 100 and the outer ring 200 include ceramics.

When the vapour deposition machine 1 is under an idle condition (as shown in FIG. 2A), the workpiece 14 is in a machine idle position; that is, the workpiece 14 is placed on the workpiece stage 12, and the inner ring 100 is seated on the outer ring 200. Specifically, the outer stepped portion 123 (as shown in the enlarged view of FIG. 1B) of the inner ring 100 corresponds to the inner stepped portion of the outer ring 200, so the inner ring 100 is engaged with the outer ring 200. In an embodiment, when the workpiece 14, such as a six-inch wafer with a flat, is in a machine idle position, the flat of the workpiece 14 corresponds to the first line portions 104 and 106 of the inner edge 100a of the inner ring 100.

When the vapour deposition machine 1 is under an active condition (as shown in FIG. 2B), the workpiece stage 12 with the workpiece 14 seated thereon is raised, until the workpiece 14 is in contact with the annular plane 118 of inner ring 100. The workpiece 14 then lifts the inner ring 100 to the machine active position together. Thereafter, a surface deposition process is performed to the workpiece 14.

It is noted that, when the workpiece 14 lifts the inner ring 100 of the workpiece clamp 10 to the machine active position together, the inner ring 100 may slightly shift due to the collision between the inner ring 100 and the workpiece 14. However, with the specific design of the first line portions 104 and 106 of the inner edge 100a of the inner ring 100, the shift of the inner ring 100 is limited, so the abnormal peripheral indent (e.g., no dent or excess dent) is not observed.

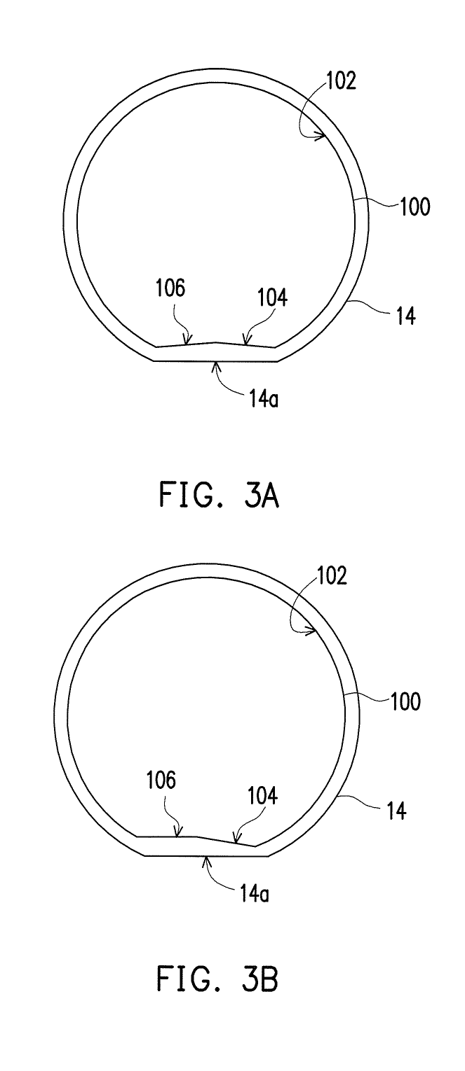

Specifically, when the workpiece 14 and inner ring 100 of the workpiece clamp 10 are under a normal or non-shift condition, the flat 14a of the workpiece 14 substantially corresponds to the first line portions 104 and 106 of the inner ring 100, as shown in FIG. 3A. Besides, although it is not shown in FIG. 3A, the second line portion 114 of the outer edge 100b substantially corresponds to the flat 14a of the workpiece 14.

When the workpiece 14, the inner ring 100 of the workpiece clamp 10 or both are under a shift condition, the second line portions 114 and 116 of the outer edge 100b of the inner ring 100 stop the shift when pressed against the outer ring 200, thus stopping the shift of the inner ring 100. Besides, due to the specific design of the first line portions 104 and 106 of the inner ring 100, the workpiece 14 can be produced in specification, as shown in FIG. 3B.

It has been the observation of the inventor that, as shown in FIG. 1A, when the included angle θ₁ between the connecting line 108 and each of the first line portions 104 and 106 is 90 degrees (i.e., the flat of the inner ring 100 is linear), the inner ring shift occurs. When the included angle θ₁ between the connecting line 108 and each of the first line portions 104 and 106 is from about 91 degrees to 92 degrees (i.e., the flat of the inner ring 100 is slightly concave), the improved effect is obvious. When the included angle θ₁ between the connecting line 108 and each of the first line portions 104 and 106 is 93 degrees, some products are manufactured without a periphery dent. Therefore, the included angle θ₁ between the connecting line 108 and each of the first line portions 104 and 106 is designed to be greater than about 90 degrees and less than about 93 degrees, and such design has an unexpected effect of significantly alleviating the inner ring shift problem of the workpiece clamp 10.

In summary, in the present invention, the flat portions of the inner ring of the workpiece clamp are designed to have a specific angle therebetween. With such design, the inner ring shift is significantly reduced, the abnormal products are less produced, the maintenance cost is lowered, and the machine stability is enhanced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A workpiece clamp, comprising:
an inner ring, wherein an inner edge of the inner ring is divided into a circular arc portion and two first line portions, the first line portions are connected to each other and located at a notch of the circular arc portion, the circular arc portion has a circle centre, the first line portions are connected at a connecting point, and an included angle between a connecting line from the circle centre to the connecting point and each first line portion is greater than about 90 degrees and less than about 93 degrees.

2. The workpiece clamp of claim 1, wherein the included angle between the connecting line from the circle centre to the connecting point and each first line portion is greater than about 90 degrees and less than or equal to about 92 degrees.

3. The workpiece clamp of claim 1, wherein the included angle between the connecting line from the circle centre to the connecting point and each first line portion is from about 91 degrees to 92 degrees.

4. The workpiece clamp of claim 1, wherein a bottom surface of the inner ring comprises an annular plane adjacent to the inner edge and an annular ramp extending outwardly from the annular plane.

5. The workpiece clamp of claim 4, wherein an included angle between the annular plane and the annular ramp is from about 115 degrees to 125 degrees.

6. The workpiece clamp of claim 1, wherein an outer edge of the inner ring has two separate second line portions.

7. The workpiece clamp of claim 6, wherein the first line portions are opposite to one of the second line portions.

8. The workpiece clamp of claim 1, wherein the first line portions have substantially the same length.

9. The workpiece clamp of claim 1, wherein the first line portions have different lengths.

10. The workpiece clamp of claim 1, further comprising an outer ring configured to engage with the inner ring.
